(19) United States
(12) Patent Application Publication
(10) Pub. No.: US 2024/0369946 A1
(43) Pub. Date: Nov. 7, 2024

(54) OPTICAL SYSTEM FOR A METROLOGY SYSTEM AND METROLOGY SYSTEM WITH SUCH AN OPTICAL SYSTEM

(71) Applicant: Carl Zeiss SMT GmbH, Oberkochen (DE)

(72) Inventors: Matthias Wald, Jena (DE); Manuel Decker, Jena (DE); Arne Schob, Jena (DE); Markus Koch, Oberkochen (DE)

(21) Appl. No.: 18/648,644

(22) Filed: Apr. 29, 2024

(30) Foreign Application Priority Data
May 5, 2023 (DE) 102023204172.3

(51) Int. Cl. G03F 7/00

(52) U.S. Cl. CPC G03F 7/706849; G03F 7/706851

(57) ABSTRACT

An optical system for a metrology system for measuring an object has an object holder for holding the object in an object plane. A transmissive optical focusing component is arranged in the beam path of illumination light between a light source of the metrology system and an object field in the object plane. The transmissive optical focusing component is used to generate an illumination focus in the subsequent beam path of the illumination light. The transmissive optical focusing component has a focal length which is smaller than 5 mm. A detection device is used for detecting the illumination light in the beam path downstream of the object field. An imaging optical unit is used for imaging the illumination focus generated by the transmissive optical focusing component into a further illumination focus in the region of the object field. The result is an optical system, the handling of which, in particular with respect to the object arrangement, is facilitated.

### CROSS-REFERENCE TO RELATED APPLICATION

This application claims priority under 35 U.S.C. § 119 from German Patent Application DE 10 2023 204 172.3, filed on May 5, 2023, the entire contents of which are incorporated herein by reference.

### TECHNICAL FIELD

The invention relates to an optical system for a metrology system for measuring an object. The invention further relates to a metrology system for measuring an object with such an optical system.

### BACKGROUND

A metrology system of the type mentioned above is known, for example, from US 2012/0008123 A1. Further systems for measuring lithographic masks are known from the specialist articles by Na J. et al. “Application of actinic mask review system for the preparation of HVM EUV lithography with defect free mask,” Proc. of SPIE Vol. 10145, 101450M-1, by Goldberg K. et al. “Actinic mask imaging: recent results and future directions from the SHARP EUV microscope,” Proc. of SPIE Vol. 9049, 90480Y-1, and by Naulleau et al. “Electro-optical system for scanning microscopy of extreme ultraviolet masks with a high harmonic generation source,” Optics Express, Vol. 22, 20144, 2014. Another metrology system is known from U.S. Pat. No. 9,904,060. US 2010/0294949 A1 discloses a scanning microscope device.

### SUMMARY

It is an aspect of the present invention to further develop an optical system for a metrology system in such a way that its handling, in particular with respect to the object arrangement, is facilitated.

According to the invention, this aspect is achieved by an optical system comprising the features specified in Claim 1.

According to the invention, it has been found that the utilization of a transmissive optical focusing component having a short focal length does not require a correspondingly small working distance between this transmissive optical focusing component and the object. The imaging optical unit, which is connected in-between for imaging the illumination focus generated by the transmissive optical focusing component and whose function corresponds to that of a relay optical unit, makes it possible to increase the working distance. The working distance may be larger than 20 mm, may be larger than 25 mm, may be larger than 50 mm and may even be larger than 100 mm. The working distance is here the distance between the object field and the nearest component of the optical system, which is typically a component of the imaging optical unit for imaging the illumination focus generated by the transmissive optical focusing component into the further illumination focus in the region of the object field. The working distance can be measured as a real distance between nearest points of the object field and the correspondingly nearest component of the optical system, or also as a pure z-distance between the object field and a component of the optical system that overlaps therewith in the x/y-direction and lies at a distance in the z-direction.

An imaging scale of the imaging optical unit for imaging the illumination focus generated by the transmissive optical focusing component into the further illumination focus in the region of the illumination field can lie in the region of 1. In this case, the imaging optical unit mainly or exclusively serves for increasing the working distance in particular between the object field and the nearest component of the optical system. A numerical aperture in the illumination focus generated by the optical focusing component and a numerical aperture in the further illumination focus in the region of the object field are then the same. Alternatively, the imaging scale can be smaller than 1. This can be utilized in order to reduce a required refractive power of the transmissive optical focusing component, which in turn can be used to decrease an unwanted chromatic aberration of the optical system, in particular a longitudinal chromatic aberration of the transmissive optical focusing component.

The object holder can be designed to be displaceable and in particular can be operatively connected to an object displacement drive. Object displacement can be effected perpendicular to the object plane and/or along at least one coordinate spanning the object plane. A displacement accuracy of the object displacement drive along the at least one displacement direction may be better than 1 μm, can be better than 0.5 μm and can in particular be better than 250 nm. The displacement accuracy may in particular be better than 100 nm. A lower limit for the displacement accuracy typically lies in the region of 0.1 nm.

The object to be measured can be a mask, in particular a lithography mask, or reticle.

If the transmissive optical focusing component is designed as a zone plate, which is also referred to as a zone lens, the advantages of the optical system are particularly effective.

A working distance according to Claim 3 allows non-critical handling of the object without it undesirably coming into contact with components of the optical system.

An imaging optical unit according to Claim 4 has proven useful in practice. The imaging optical unit may be designed as a catoptric or as a catadioptric object optical unit.

An imaging optical unit according to Claim 5 may have in particular exactly one mirror and can then be designed with low reflection losses. Alternatively, the imaging optical unit may have two mirrors or even more than two mirrors and thus ensure imaging with small aberrations. In the ideal case, the imaging optical unit can correct or compensate for aberrations introduced by the transmissive optical focusing component.

A folding mirror according to Claim 6 enables adaptation of the optical system to structural conditions.

An aspherical mirror according to Claim 7 allows good aberration control during imaging. The imaging optical unit can have at least one mirror, whose mirror surface is designed as a free-form surface. In this way, limitations which would be present due to an axis of rotational symmetry of a spherical or aspherical mirror surface can be eliminated.

A chief ray angle according to Claim 8 enables illumination of the object with low shadowing effects and a correspondingly high-quality measurement of the object. The chief ray angle of the illumination light incident in the object field may be greater than 0° and may, for example, be greater than 0.1° or even greater than 0.5° for all beams of the illumination light.

Using an actuator according to Claim 9, it is possible to adjust the object perpendicular to the object plane. In addition, the object holder can also be displaceable by use of corresponding actuators in at least one direction parallel to the object plane, in particular in two mutually independent directions parallel to the object plane. Using the actuator for displacing the object holder perpendicular to the object plane, a 3D aerial image can be measured in particular by recording what is known as a focus stack. Here, an object image is measured in each case in different z-positions of the object holder and thus of the object.

Using a corresponding actuator for the displacement of the object holder with respect to the object plane, it is also possible to ensure separate focusing for different wavelength components of the illumination light, that is, to ensure for the corresponding wavelength component that the object is then sharply imaged into an arrangement plane or detection plane of the detection device.

The advantages of a metrology system according to Claim 10 correspond to those which have already been explained above with reference to the optical system. A spectral width Δλ/λ) (FWHM, full width at half max) of the illumination light generated by the light source may be at least 5×10⁻⁴, at least 1×10⁻³, at least 3×10⁻³, at least 5×10⁻³, at least 1×10⁻², and may, for example, lie in the range between 1/250 and 1/300.

An EUV light source according to Claim 11 enables actinic measurement, in particular of an EUV lithography mask as the object. The EUV light source can be a plasma light source.

Exemplary embodiments of the invention are explained in greater detail below with reference to the drawing, in which:

### BRIEF DESCRIPTION OF DRAWINGS

FIG. 1 schematically shows a metrology system for measuring an object;

FIG. 2 shows a top view of a zone plate as a transmissive optical focusing component for generating an illumination focus in the region of an object field of an optical system of the metrology system;

FIG. 3 shows illumination foci in the region of an object plane of the optical system for different wavelength components of illumination light from a light source of the metrology system in a beam path downstream of the zone plate;

FIG. 4 shows an embodiment of an illumination light beam path of the optical system downstream of the zone plate up to a spectrally sensitive embodiment of the detection device of the optical system;

FIG. 5 schematically shows a variant of use of the detection device according to FIG. 4 with the additional use of an object holder, which is displaceable perpendicular to the object plane by use of an actuator;

FIG. 6 shows an illustration similar to FIG. 4 of a further embodiment of a spectrally sensitive detection device of the optical system, wherein a grating is designed as a bandpass filter for filtering at least one selected wavelight component from the illumination light;

FIG. 7 shows a further embodiment of a beam path of the optical system between the zone plate and the object field using an imaging optical unit for imaging the illumination focus generated by the zone plate into a further illumination focus in the region of the object field; and

FIG. 8 shows an enlargement of the detail VIII in FIG. 7.

### DETAILED DESCRIPTION

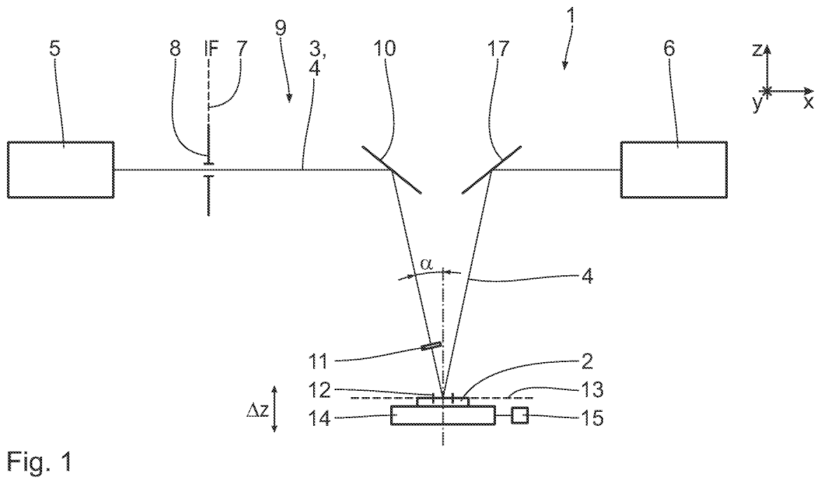

FIG. 1 shows highly schematically a metrology system 1 for measuring an object 2. An example of the object 2 to be measured is a lithography mask for projection lithography for the production of microstructured or nanostructured semiconductor components. A beam path of a chief ray 3 of illumination light 4 between a light source 5 and a detection device 6 of the metrology system 1 is shown.

The light source 5 is an EUV light source for generating the EUV illumination light 4 with a central used wavelength in the range between 5 nm and 30 nm, in particular of 13.5 nm. A spectral width Δλ/λ) (FWHM, full width at half max) of the EUV illumination light 4, which is used for the illumination of the object 2, is at least 1×10⁻⁴ and may, for example, lie in the range between 1/250 and 1/300. The light source 5 can be a plasma light source or a high-harmonic generation (HHG) light source.

Arranged in the beam path of the illumination light 4 downstream of the light source 5 is an intermediate focus plane 7, in which an intermediate focus stop 8 is arranged. The intermediate focus stop 8 is used to separate the used illumination light 4 from debris which is in particular undesirably carried along. Downstream of the intermediate focus stop 8, an extraneous light filter for separating the used illumination light 4 from wavelength components undesirably carried along in the beam path can be arranged in the beam path of the illumination light 4.

Downstream of the light source 5, the illumination light 4 is guided by an optical system 9 of the metrology system 1.

To clarify the positional relationships between components of the metrology system, a Cartesian xyz coordinate system is drawn in FIG. 1. The x-direction runs to the right in FIG. 1. The y-direction runs into the plane of the drawing at right angles thereto in FIG. 1. The z-direction runs upwards in FIG. 1.

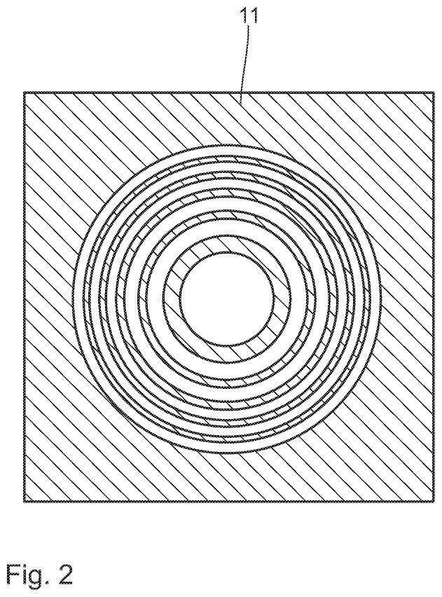

In the variant of the optical system 9 shown in FIG. 1, a folding mirror 10 for the illumination light 4 is arranged in the beam path of the illumination light 4 downstream of the intermediate focus stop 8. In the beam path downstream of the folding mirror 10, a zone plate 11 of the optical system 9 is arranged, which is shown in a top view in FIG. 2. A zone plate is a device which has a light-guiding function based on diffraction. As a rule, a zone plate comprises a set of concentric rings or zones having alternate light-effecting characteristics, i.e., transparent/opaque or reflective/absorbing. As a rule, such rings or zones are spaced such that reflected light constructively interferes at a desired spot or focus. The zone plate 11 represents a transmissive optical focusing component, which is arranged in the beam path of the illumination light 4 between the light source 5 and an object field 12 in an object plane 13 of the optical system 9.

An object holder 14 of the optical system is used to hold the object 2 in the object plane 13 such that a portion of the object 2 is located in the object field 12. Via an actuator 15, the object holder 14 is displaceable perpendicular to the object plane 13, as is illustrated by a double-headed displacement arrow Δz in FIG. 1. The actuator 15 can be designed as a linear motor with a moving part and a stator part, in particular may be designed as a Lorentz-type actuator.

The zone plate 11 generates an illumination focus 16 (see also FIG. 4) in the region of the object field 12.

A chief ray angle α (see FIG. 1), with which the illumination light 4 is incident in the object field 12, may be smaller than 6°.

An object-side numerical aperture of the illumination light beam path can lie in the range of 0.1.

The object 2 is designed as a reflective object. Illumination light 4 reflected by the object 2 is guided as detection light from the optical system 9 to the detection device 6. In the embodiment according to FIG. 1, a further folding mirror 17 is arranged in the beam path of the detection light between the object 2 and the detection device 6.

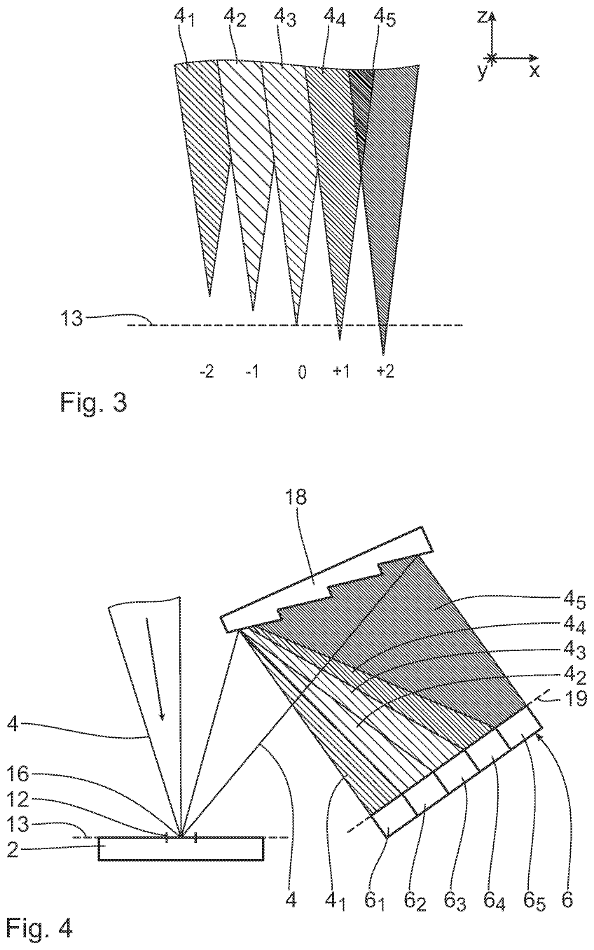

FIG. 3 illustrates focusing conditions in the region of the object plane 13 due to the dispersion of the zone plate 11, i.e., due to a wavelength dependency of the diffraction effect of the zone plate. Different wavelength components 4₁ to 4₅ are shown split up in the x-direction for illustration purposes in FIG. 3. For example, the wavelength component 4₁ is the one with the largest wavelength and the wavelength component 4₅ is the component with the smallest wavelength within the spectral width of the used illumination light. Due to the dispersion of the zone plate 11, the wavelength components 4₁ to 4₅ are focused at different z-positions in the illumination focus 16 in the region of the object plane 13.

FIG. 4 shows a configuration of the guidance of the illumination light 4 downstream of the object 2 towards the detection device 6. A dispersive optical component 18, i.e., an optical component 18 having a wavelength-depending light-guiding effect, e.g., in the form of a grating is arranged in the beam path of the detection light 4 between the object field 12 and the detection device 6. Alternative to the grating, the dispersive optical component 18 may be embodied as a component made of a material exhibiting a wavelength-dependent refractive index, e.g. a prism. Alternatively, the dispersive optical component 18 may be realized as an optical component carrying a dispersive coating which may be realized as a transmissive or as a reflective coating for the detection light 4.

The dispersive optical component 18 will spatially separate two wavelength components with a wavelength difference Δλ/λ) of at least 1/1000 by a separation angle of at least 1×10⁻⁴. Assuming a distance between the dispersive optical component 18 and the detection device 6 of 10 cm this will result in a split of such separated two wavelength components of at least 10 μm. Such split may equal a pixel distance on the detection device 6. The grating 18 spatially splits up the different wavelength components 4¹ to 4₅ of the detection light 4. The wavelight components 4₁ to 4₅ of the detection light 4 are at least partially spatially separated in the beam path following the grating 18.

The detection device 6 is arranged in an arrangement plane or detection plane 19, in which this at least partial spatial separation of the wavelength components 4₁ to 4₅ takes place. The detection device 6 is designed as a sensor line with, in the illustrated embodiment, five sensor elements 6₁ to 6₅ for at least partially separate detection of the wavelength components 4¹ to 4₅ of the illumination or detection light 4 in the beam path downstream of the object field 12. Depending on the design, the detection device can have two, three, five, ten or even more sensor elements 6ᵢ. The detection device 6 can be designed as a sensor line or as a two-dimensional sensor array, for example in the form of a charge-coupled device (CCD) or complementary metal-oxide-semiconductor (CMOS) array.

With the aid of the detection device 6 according to FIG. 4, it is possible at a z-position of the object 2 to resolve information about the object 2 from different z-heights of the object structures located there via the various wavelength components 4¹ to 4₅ and to detect them in z-resolved fashion without z-displacement of the object 2 (single-shot) using the spectrally sensitive detection by use of the grating 18 and the detection device 6.

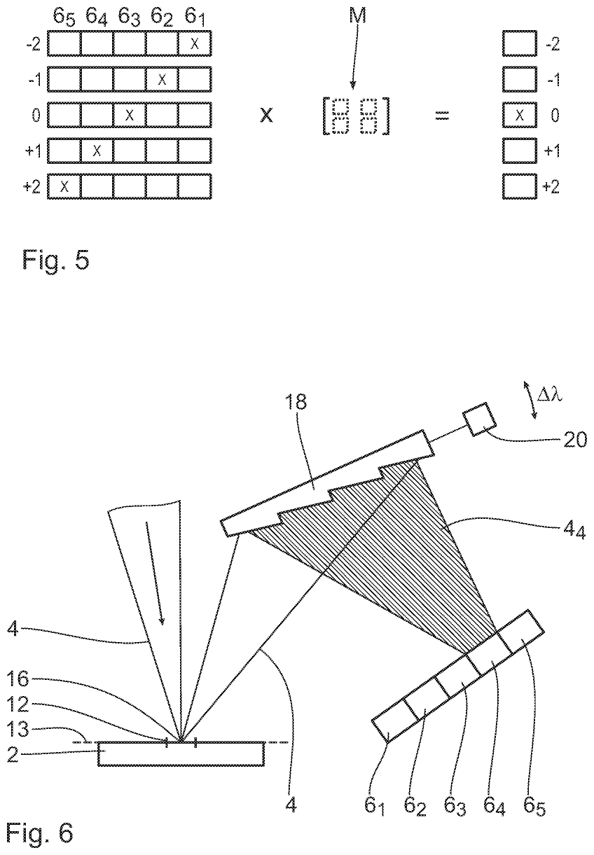

Alternatively or additionally, the z-actuator 15 can be used in combination with the spectrally sensitive detection according to FIG. 4, as is schematically illustrated with reference to FIG. 5.

The first column of FIG. 5 illustrates a total of five different z-positions of the object 2, which can be set via the actuator 15 with the object holder 14. These z-positions are numbered −2, −1, 0, +1 and +2.

FIG. 5 schematically shows in the second column a measurement result of the sensor line detection device 6 according to FIG. 4 at these different z-positions of the object 2. At the z-position −2, the signal at the sensor element 6₁ is greatest, since the object plane 13 there coincides with the illumination focus 16 of the wavelength component 4¹. The maximum detection intensity, which is measured with the sensor line detection device 6, shifts accordingly to the sensor elements 6₂, 6₃, 6₄ and 6₅ at the further z-positions −1, 0, +1 and +2, as is illustrated in the second column of FIG. 5 in each case by an “X” at the respective sensor element 6ᵢ.

By use of a deconvolution matrix M (shown in FIG. 5 in the third column after a deconvolution operator), which is previously generated by calibration, the measurement result for example for the z-position “z=0” of the object plane 13 is deconvolved into a signal which exclusively contains signal contributions at this z-displacement position of the object 2 by way of the object holder 14, which is illustrated by way of example in the last line of FIG. 5. The adjusted detection signals for the other z-values −2, −1, +1 and +2 can be generated accordingly via further deconvolution matrices M. Properties of the optical system 9 are included in the deconvolution matrices M, in particular previously measured channel crosstalk information between the sensor elements 6; of the sensor line detection device 6.

FIG. 6 shows a further use of a detection arrangement according to the type of FIG. 4. Here, the grating 18 is not used for single-shot detection of the various z-object structure heights, but as a bandpass filter for filtering at least one selected wavelength component out of the used spectral width of the illumination or detection light 4. FIG. 6 shows a position of the grating 18 for the use of the wavelength component 4₄, which is incident on the sensor element 6₄. The other wavelength components 4₁ to 4₃ and 4₅ do not contribute to the exposure of the sensor elements 6ᵢ at this position of the grating 18.

For use as a bandpass filter, the grating 18 is operatively connected to an actuator 20 for swivelling the grating 18 and thus for selecting the wavelength component 4ᵢ used for the detection, which is shown by a double-headed arrow Δλ in FIG. 6.

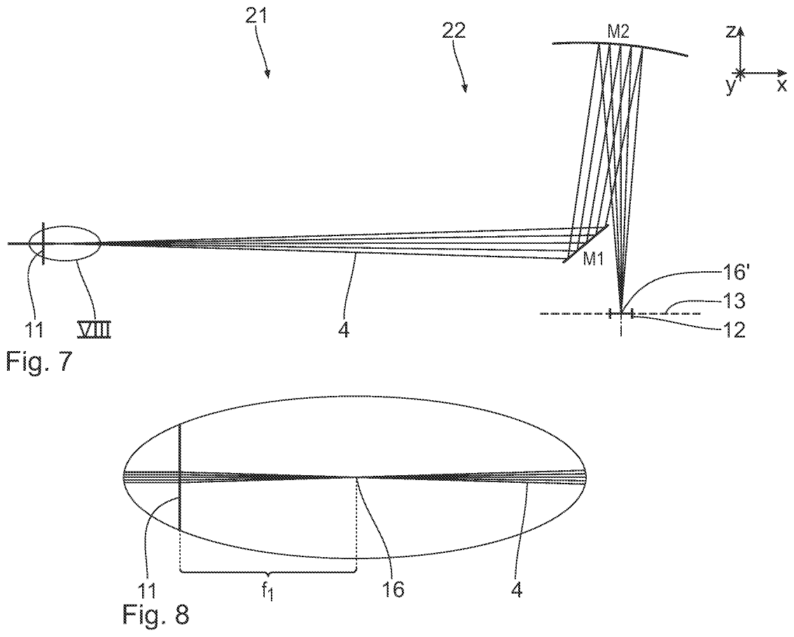

FIG. 7 shows a beam path of a variant of an optical system 21 for the metrology system 1. Components and functions which have already been explained above in connection with FIGS. 1 to 6 are denoted with the same reference signs and are not discussed again in detail.

FIG. 7 shows a variant of the beam path of the illumination light 4 based on five selected individual rays between the zone plate 11 and the object field 12. In contrast to the beam path according to FIG. 1, the beam path of the illumination light 4 passes through the zone plate 11 along the x-direction. In this embodiment of the beam path according to FIG. 7, therefore the folding mirror 10 is omitted.

The zone plate 11 has a focal length f₁ (see FIG. 8) which is smaller than 5 mm, which may be smaller than 2 mm, may be smaller than 1 mm and, in the illustrated embodiment, lies in the range of 0.5 mm.

For imaging the illumination focus 16 generated by the zone plate 11 into a further illumination focus 16′ in the region of the object field 12, an imaging optical unit 22 of the optical system 21 according to FIG. 7 is used. The imaging optical unit 22 is designed as a mirror optical unit. In the embodiment according to FIG. 7, the imaging optical unit 22 has two mirrors, to be specific a first mirror M1 in the beam path of the illumination light 4 downstream of the zone plate 11, and a further, downstream mirror M2.

In the embodiment according to FIG. 7, the mirror M1 is designed as a planar folding mirror. Alternatively, the mirror M1 can also have an imaging effect. The mirror M2 is designed as an aspherical mirror. Alternatively, the mirror M2 can also be designed as a spherical mirror. The mirror M2 can be designed in particular as a free-form surface mirror.

A working distance between the zone plate 11 and the object field 12 can be significantly larger than the focal length f₁ due to the intermediate imaging optical unit 22 and may be larger than, for example, 10 mm, may be larger than 20 mm, may be larger than 50 mm and may be 100 mm or more. The working distance is the distance between the object field and the nearest component of the optical system, which is typically a component of the imaging optical unit for imaging the illumination focus, generated by the transmissive optical focusing component, into the further illumination focus in the region of the object field. The working distance can be measured as a real distance between the nearest points of the object field and the corresponding nearest component of the optical system, or as a pure z-distance between the object field and a component of the optical system that overlaps the object field in the x/y-direction and is remote in the z-direction.

Due to the intermediate imaging optical unit 22, it is possible in particular to set a desired dispersion in the design regardless of the necessary working distance, for example with the aim of being particularly favourable for the combination with the detection device 6. It is advantageous in this case if the dispersion between adjacent sensor elements 6; of the spectral detection device 6 leads to an offset Δz of, for example, 50 nm-200 nm, since this can correspond to a z-interval in a z-stack or image stack recorded by the metrology system 1.

An imaging scale when imaging the object field 12 into an image field in the region of the arrangement plane 19 may be greater than 10, may be greater than 25, may be greater than 50, may be greater than 100, may be greater than 250, may be greater than 300 and may lie in the range of 500 or 1000, for example.

To measure the structure of the object 2, an image of the object structure in the object field 12 is recorded by the detection device 6. Depending on the measurement method, either a single image is recorded or an image stack (aerial image) in a plurality of z-positions, in which case the object 2 is displaced into corresponding z-positions by use of the object holder 14 and the actuator 15.

A number of embodiments of the invention have been described. Nevertheless, it will be understood that various modifications may be made without departing from the spirit and scope of the invention. For example, the distance between the dispersive optical component and the detection device, the split of the separated two wavelength components, and the pixel distance on the detection device may be different from the examples described above. Accordingly, other embodiments are within the scope of the following claims.

What is claimed is:

1. An optical system for a metrology system for measuring an object,
comprising an object holder for holding the object in an object plane,
comprising a transmissive optical focusing component, which is arranged in the beam path of illumination light between a light source of the metrology system and an object field in the object plane, for generating an illumination focus in the beam path of the illumination light downstream of the transmissive optical focusing component,
wherein the transmissive optical focusing component has a focal length which is smaller than 5 mm,
comprising a detection device for detecting the illumination light in the beam path downstream of the object field,
comprising an imaging optical unit for imaging the illumination focus generated by the transmissive optical focusing component into a further illumination focus in the region of the object field.

2. The optical system of claim 1, wherein the transmissive optical focusing component is designed as a zone plate.

3. The optical system of claim 2, wherein a working distance between the zone plate and the object field which is larger than 10 mm.

4. The optical system of claim 1, wherein the imaging optical unit is designed as a mirror optical unit.

5. The optical system of claim 1, wherein the imaging optical unit has at least one mirror.

6. The optical system of claim 5, wherein the imaging optical unit has at least one folding mirror.

7. The optical system of claim 5, wherein the imaging optical unit has at least one aspherical mirror.

8. The optical system of claim 1, wherein a chief ray angle of the illumination light incident in the object field is smaller than 6°.

9. The optical system of claim 1, comprising an actuator for displacing the object holder perpendicular to the object plane.

10. A metrology system for measuring an object, the metrology system comprising:
an optical system according to claim 1,
a light source for generating illumination light.

11. The metrology system of claim 10, wherein the light source is an EUV light source.

12. The metrology system of claim 11, wherein the transmissive optical focusing component is designed as a zone plate.

13. The metrology system of claim 12, wherein a working distance between the zone plate and the object field which is larger than 10 mm.

14. The metrology system of claim 11, wherein the imaging optical unit is designed as a mirror optical unit.

15. The metrology system of claim 11, wherein the imaging optical unit has at least one mirror.

16. The metrology system of claim 15, wherein the imaging optical unit has at least one folding mirror.

17. The metrology system of claim 15, wherein the imaging optical unit has at least one aspherical mirror.

18. The metrology system of claim 11, wherein a chief ray angle of the illumination light incident in the object field is smaller than 6°.

19. The metrology system of claim 11, comprising an actuator for displacing the object holder perpendicular to the object plane.

20. The optical system of claim 2, wherein the imaging optical unit is designed as a mirror optical unit.
